(19) United States
(12) Patent Application Publication
(10) Pub. No.: US 2008/0042157 A1
(43) Pub. Date: Feb. 21, 2008

(54) SURFACE MOUNT LIGHT EMITTING DIODE PACKAGE

(75) Inventors: HUA-HSIN SU, Taoyuan County (TW); KUAN-YU HUANG, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: FORMOSA EPITAXY INCORPORATION, Tao-Yung Hsien (TW)

(21) Appl. No.: 11/464,832

(22) Filed: Aug. 16, 2006

(51) Int. Cl. H01L 33/00

(52) U.S. Cl. 257/99

(57) ABSTRACT

A surface mount light emitting diode package (surface mount LED package) includes a leadframe, a LED chip, a plurality of conductors and an encapsulant. The LED chip is disposed over the leadframe. The LED chip has an active surface facing the leadframe and a plurality of electrodes is disposed on the active surface. In addition, the conductors are disposed between the leadframe and the LED chip, the electrodes are electrically connected to the leadframe through the conductors and the encapsulant encapsulates the LED chip and a part of the leadframe. In this way, the surface mount LED package of the present invention has better luminescence efficiency.

### BACKGROUND OF THE INVENTION

1. Field of Invention

The present invention relates to a light emitting diode package (LED package), and particularly to a surface mount light emitting diode package (surface mount LED package).

2. Description of the Related Art

Since an LED has, such as long lifetime, downsized volume, high shock-proof behavior, small heat discharge, low electricity-consumption and so on, LEDs have been widely applied in electrical appliances, various instrument indicator lights or light sources. In recent years, as the development of an LED towards multi-color and high brightness, the application of the LED has been expanded to mega-size outdoor display boards and traffic lights. In the future, an LED may substitute a tungsten lamp or a mercury lamp for a lighting source because the LED is electricity-saving and environment protection friendly.

FIG. 1 is a diagram of a conventional surface mount LED package. Referring to FIG. 1, a surface mount light emitting diode package (surface mount LED package) 100 includes a leadframe 110, a light emitting diode chip (LED chip) 120, two bonding wires 130 and a transparent encapsulant 140. The LED chip 120 is adhered on the leadframe 110 by a die-bonding adhesive 102. The LED chip 120 has two electrodes 122 and each electrode 122 is electrically connected to the leadframe 110 through a bonding wire 130. Besides, the transparent encapsulant 140 encapsulates the LED chip 120, the bonding wires 130 and a part of the leadframe 110. In other words, in addition to enabling the light emitted from the LED 120 to transmit to outside, the transparent encapsulant 140 can prevent the LED chip 120 from being dust polluted or the bonding wires 130 from being damaged.

Note that the LED chip is adhered on the leadframe by a die bonding adhesive. Since the light reflectivity of the die bonding adhesive is poor, the illumination of the surface mount LED package is reduced. In addition, the above-described electrodes are electrically connected to the leadframe through the bonding wires and the bonding wires would hide a part of the light emitted from the LED chip, so that the luminescence of the surface mount LED package is affected. Therefore, how to improve the illuminating efficiency of a surface mount LED package is an important issue.

### SUMMARY OF THE INVENTION

Accordingly, the present invention is directed to provide a surface mount light emitting diode package (surface mount LED package) having a better luminescence efficiency.

The present invention is directed to provide a method for fabricating a surface mount LED package, so that the fabricated surface mount LED package has a better luminescence efficiency.

As embodied and broadly described herein, the present invention provides a surface mount LED package including a leadframe, a light emitting diode chip (LED chip), a plurality of conductors and an encapsulant. The LED chip is disposed over the leadframe and has an active surface facing the leadframe, and a plurality of electrodes disposed on the active surface. Besides, the conductors are disposed between the leadframe and the LED chip. The electrodes are electrically connected to the leadframe through the conductors, while the encapsulant encapsulates the LED chip and a part of the leadframe.

In an embodiment of the present invention, the conductors may be gold balls, a conductive resin, or a solder.

In an embodiment of the present invention, the encapsulant is a transparent encapsulant.

In an embodiment of the present invention, the surface mount LED package further comprises a fluorescence powder mixed in the encapsulant.

The present invention further provides a method for fabricating a surface mount LED package, and the method includes the following steps. First, a leadframe is provided. Next, an LED chip is provided, wherein the LED chip has an active surface and a plurality of electrodes is disposed on the active surface. Afterwards, the LED chip is put over the leadframe and electrically connected to the leadframe through a plurality of conductors. Finally, an encapsulant is formed for encapsulating the LED chip and a part of the leadframe.

In an embodiment of the present invention, the conductors may be gold balls, a conductive resin or a solder.

In an embodiment of the present invention, the encapsulant is a transparent encapsulant.

In an embodiment of the present invention, the surface mount LED package further comprises a fluorescence powder mixed in the encapsulant.

In an embodiment of the present invention, the encapsulant formed on the LED chip and on the part of the leadframe is formed by dispensing process.

In an embodiment of the present invention, the conductor is formed on the LED chip in advance to electrically connect the LED chip and the leadframe.

In an embodiment of the present invention, the conductor is formed on the leadframe in advance to electrically connect the LED chip and the leadframe.

In the surface mount LED package of the present invention, the LED chip is electrically connected to the leadframe by using a flip chip technology. Thus, luminescence efficiency of the surface mount LED package is better than prior art.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a diagram of a conventional surface mount LED package.

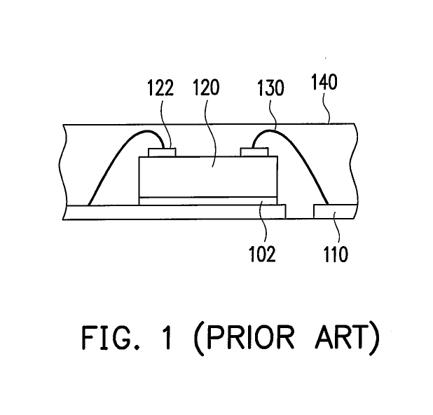

FIGS. 2A˜2D illustrate a process for fabricating a surface mount LED package provided by an embodiment of the present invention.

### DESCRIPTION OF THE EMBODIMENTS

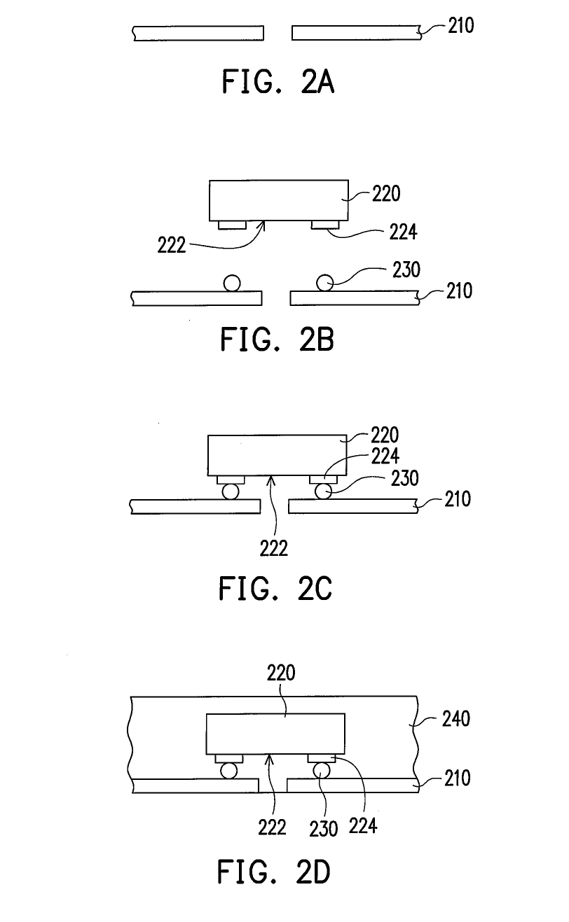

FIGS. 2A˜2D illustrate the process for fabricating a surface mount LED package provided by an embodiment of the present invention. First, referring to FIG. 2A, a leadframe 210 is provided. In the embodiment, the leadframe 210 can be a copper leadframe or a leadframe made of other conductive materials. In addition, according to design requirement, the present invention allows optionally plating other metal layers on the surface of the leadframe.

Next, referring to FIG. 2B, an LED chip 220 is provided. The LED chip 220 has an active surface 222 and a plurality of electrodes 224 disposed on the active surface 222. In the embodiment, the LED chip 220 can be an LED chip for producing white light, blue light, ultraviolet light or an LED chip producing other color light.

Afterwards, referring to FIG. 2C, the LED chip 220 is put over the leadframe 210 and is electrically connected to the leadframe 210 through a plurality of conductors 230 disposed between the leadframe 210 and the LED chip 220. At this time, the active surface 222 of the LED chip 220 faces the leadframe 210. In other words, the present invention uses a flip chip technology to electrically connect the LED chip 220 to the leadframe 210. In the embodiment, the conductor 230 can be fabricated in advance on the leadframe 210 (as shown in FIG. 2B), followed by joining the electrodes 224 of the LED chip 220 with the leadframe 210 through the conductors 230 for the purpose of electrical connection. The conductors 230 are, for example, gold balls, a conductive resin or a solder. Certainly, the conductors 230 can also be fabricated in advance on the electrodes 224 of the LED chip 220, followed by joining the conductors 230 on the electrodes 224 with the leadframe 210 for the purpose of electrical connection.

After the LED chip 220 with the leadframe 210 are joined, an encapsulant 240 is formed on the LED chip 220 and a part of the leadframe 210 in the present embodiment for encapsulating the LED chip 220 and the part of the leadframe 210. The method for encapsulating the LED chip 220 and the part of the leadframe 210 is, for example, a dispensing process. Except for the dispensing process, a molding technology or other appropriate technologies can be also used in the present invention to achieve the purpose of encapsulating the LED chip 220 and the part of the leadframe 210. In this way, the LED chip 220 is able to be avoided from damage by an external force or from dust pollution.

In an embodiment of the present invention, the encapsulant 240 is, for example, a transparent encapsulant, such as silicone resin, to facilitate the light emitted from the LED chip 220 to propagate to the outside environment in more amount. Note that the present invention does not limit the color of the encapsulant 240, i.e. the encapsulant 240 can have any color, which determines the color the LED package appears during an operation.

In an embodiment of the present invention, an LED chip producing ultraviolet light can be used, wherein red fluorescence powder, green fluorescence powder or blue fluorescence powder is mixed into the encapsulant 240, so that the LED package is able to transmit red light, green light, or blue light, respectively. In addition, a combination in an appropriate proportion of red fluorescence powder, green fluorescence powder and blue fluorescence powder can be used in the present invention as well to make an LED package produce white light.

In another embodiment of the present invention, an LED chip producing blue light with the encapsulant 240 mixed with yellow fluorescence powder can be used to make the LED package produce white light. In more detail, under the combination of the blue light LED chip and the yellow fluorescence powder, the yellow fluorescence powder is irradiated by the blue light transmitted from the blue light LED chip and then produces yellow light, further the produced yellow light and the blue light are light interfused and consequently produce white light. However, the present invention does not limit the color of the light produced by the surface mount LED package. A manufacturer can select a desired fluorescence powder for adding into the encapsulant to meet the design requirement.

Accordingly, for advancing the luminous efficiency of a surface mount LED package, the leadframe can have a metal plating film (not shown), which is formed on the leadframe by using, for example, a plating process. The material of the metal layer can be silver to make the metal layer have good light reflectivity. In other words, in this way, the light transmitted from the LED chip can be reflected to the outside environment in more amount by the metal layer and the luminescence efficiency of the surface mount LED package is accordingly advanced.

In summary, the present invention adopts a flip chip technology to electrically connect an LED chip to a leadframe. Compared with the prior art, where the luminescence efficiency of a surface mount LED package is affected by the lower light reflectivity of the die bonding adhesive; or a part of the light transmitted from a LED chip is hidden by the bonding wires thereof, thus, the light transmitted from an LED chip of the present invention can travel to the outside environment in more amount. Hence, the luminescence efficiency of the surface mount LED package is advanced.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A surface mount light emitting diode package (surface mount LED package), comprising:
a leadframe;
an LED chip, disposed over the leadframe, wherein the LED chip has an active surface facing the leadframe and a plurality of electrodes disposed on the active surface;
a plurality of conductors, disposed between the leadframe and the LED chip, wherein the electrodes are electrically connected to the leadframe through the conductors; and
an encapsulant, encapsulating the LED chip and a part of the leadframe.

2. The surface mount LED package as recited in claim 1, wherein the conductors comprise gold balls, conductive resin or solder.

3. The surface mount LED package as recited in claim 1, wherein the encapsulant is a transparent encapsulant.

4. The surface mount LED package as recited in claim 1, further comprising a fluorescence powder mixed in the encapsulant.

5. A method for fabricating a surface mount LED package, comprising:
providing a leadframe;
providing an LED chip, having an active surface and a plurality of electrodes disposed on the active surface;
putting the LED chip over the leadframe and electrically connecting the LED chip to the leadframe through a plurality of conductors; and
forming an encapsulant to encapsulate the LED chip and a part of the leadframe.

6. The method for fabricating a surface mount LED package as recited in claim 5, wherein the conductors comprise gold ball, conductive resin or solder.

7. The method for fabricating a surface mount LED package as recited in claim 5, wherein the encapsulant is a transparent encapsulant.

8. The method for fabricating a surface mount LED package as recited in claim 5, wherein the encapsulant is mixed with fluorescence powder.

9. The method for fabricating a surface mount LED package as recited in claim 5, wherein the method for forming the encapsulant comprises dispensing process.

10. The method for fabricating a surface mount LED package as recited in claim 5, wherein the conductors are formed on the LED chip in advance to electrically connect the LED chip and the leadframe.

11. The method for fabricating a surface mount LED package as recited in claim 5, wherein the conductors are formed on the leadframe in advance to electrically connect the LED chip and the leadframe.
